(19) United States
(12) Patent Application Publication
(10) Pub. No.: US 2008/0023139 A1
(43) Pub. Date: Jan. 31, 2008

(54) Plasma processing apparatus and plasma processing method

(76) Inventors: Naoki Yasui, Kudamatsu (JP); Hiroho Kitada, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/512,116

(22) Filed: Aug. 30, 2006

(30) Foreign Application Priority Data
Jul. 31, 2006 (JP) 2006-207341

(51) Int. Cl. H01L 21/306; C23F 1/00; C23C 16/00

(52) U.S. Cl. 156/345.24; 156/345.54; 156/345.43; 156/345.27; 156/345.28; 118/723 E; 118/724; 118/728

(57) ABSTRACT

The invention relates to a plasma processing apparatus and a plasma processing method and particularly relates to a plasma processing apparatus suitable for executing an etching processing of a work by using plasma.

### BACKGROUND OF THE INVENTION

This invention relates to a plasma processing apparatus and a plasma processing method. More particularly, the invention relates to a plasma processing apparatus that is suitable for conducting or subjecting a work or material to be processed to an etching processing by using plasma.

Dry etching using plasma has generally been executed in semiconductor fabrication processes. Various systems have been employed for plasma processing apparatuses for executing dry etching.

Generally, a plasma processing apparatus includes a vacuum processing chamber, a gas feeder connected to the vacuum processing chamber, a vacuum exhaust system for keeping an internal pressure of the vacuum processing chamber at a desired value, an electrode for supporting a wafer substrate and a plasma generation unit for generating plasma inside the vacuum processing chamber. When a processing gas supplied from a shower plate, etc, into the vacuum processing chamber is brought into a plasma state by the plasma generation unit, the etching processing of the wafer substrate held by the wafer holding electrode is executed.

To secure uniform etching performance throughout the entire in-plane of the wafer substrate, the etching reaction must be uniformly carried out throughout the wafer. In practice, however, a temperature distribution on the wafer surface is not uniform owing to influences of plasma distribution and radiation from the sidewall of the vacuum processing chamber, and the etching reaction non-uniformly proceeds inside the wafer plane.

As described in JP-A-63-216487, the wafer holding electrode in the plasma processing apparatus according to the prior art generally has the construction in which a coolant is supplied from a coolant feeder having a temperature controller to an electrode substrate and a helium gas for heat transfer is introduced to the back of the wafer to control the wafer temperature. To render the wafer temperature uniform inside the plane, an electrode in which wafer contact zones and grooves for heat transfer are distributed on the electrode surface, an electrode using two systems for the heat transfer gas (JP-A-7-249586 and JP-A-1-251735) and an electrode having two systems of coolant feeding systems in an electrode substrate (JP-A-9-17770) are known.

### SUMMARY OF THE INVENTION

To control the temperature distribution inside the wafer plane, a wafer holding electrode which supplies a heat transfer gas to the back of the wafer through two systems and a wafer holding electrode which has two systems of coolant feeding systems on an electrode substrate are known in the wafer holding electrode of the plasma processing apparatus according to the prior art.

Even when the wafer temperature is rendered uniform by supplying two systems of heat transfer gases to the wafer holding electrode, however, its effect is not great. For, a processing gas seed, a processing gas pressure and a plasma distribution greatly change depending on the kind of films deposited onto the wafer and the temperature distribution of inside the wafer plane greatly changes during the plasma processing with this change, too. In the plasma processing apparatus using two systems of heat transfer gases, regions having a difference of thermal conductivities are fixed by the heat transfer gas pressure. Therefore, the plasma processing apparatus cannot cope with a large change of the wafer temperature distribution when such a change takes place. Because this method adjusts the wafer temperature by means of only the difference of the thermal conductivities of the heat transfer gases, the contact thermal conductivity of a contact zone at which the wafer and the electrode keep mutual contact cannot be changed with the result that the variable range of the wafer temperature is narrow.

Similarly, when the wafer temperature is adjusted by using the difference of the thermal conductivities by the kind of the heat transfer gases supplied to the two systems, respectively, the plasma processing apparatus cannot cope with the great change of the wafer temperature distribution and the variable range of the wafer temperature is narrow. When the heat transfer gas pressure is low, the contact thermal conductivity of the portion at which the wafer and the electrode keep mutual contact strongly depends on the surface roughness of the electrode surface. Therefore, stability of the wafer temperature is adversely affected and the yield gets deteriorated when the surface roughness of the electrode surface changes with time due to the plasma processing.

Furthermore, when the laminate film formed by depositing a plurality of materials on the wafer is etched, the etching processing must be serially carried out under the optimal condition (processing gas kind, processing gas pressure, plasma distribution, etc) of the materials of each film. When a desired etching processing is applied, the optimal condition of the etching processing varies depending on the film of each material in the etching processes (hereinafter called “step etching”) for serially executing each phase (hereinafter called “step”) of the etching processing in accordance with a predetermined order and the temperature distribution inside the wafer plane greatly changes during the plasma processing. In the plasma processing apparatus according to the prior art that uses two systems of coolants for the electrode substrate, the flow paths of the coolants are fixed. Consequently, the plasma processing apparatus cannot cope with the change when the necessary wafer temperature distribution greatly changes. To greatly change the temperature distribution, it is necessary to change the coolant temperatures of the coolants of the two systems, and then to change the temperature distribution inside the wafer plane by heat conduction between the wafer and the electrode substrate after the in-plane temperature distribution of the electrode substrate is adjusted. Therefore, a long time is necessary for changing the temperatures of the coolants and the wafer temperature distribution cannot be changed at a high speed between the steps.

On the other hand, as a wafer diameter has become as large as φ300 mm, the plasma distribution inside the wafer plane and the distribution of the reaction products have become more non-uniform. To cope with this problem, a method of controlling the wafer temperature inside the plane so that the etching performance becomes uniform has been required instead of making the wafer temperature distribution uniform inside the plane. In other words, high precision temperature control inside the wafer plane has become necessary.

It is therefore an object of the invention to provide a plasma processing apparatus and a plasma processing method each capable of controlling highly precisely a temperature distribution inside a wafer plane and expanding the range of a wafer temperature that can be controlled.

It is another object of the invention to provide a plasma processing apparatus and a plasma processing method each capable of changing at a high speed a wafer temperature distribution between steps for processing a film layer on a wafer.

The objects described above can be accomplished by a plasma processing apparatus including a processing chamber having a vacuum exhaust device connected thereto and capable of reducing an internal pressure thereof, a device for supplying a gas into the processing chamber, a plasma generation unit for generating plasma inside the processing chamber and a unit for attracting and fixing a work or material to be processed onto an electrode whose temperature is controlled, by electrostatic force, including a plurality of units for independently supplying or exhausting a heat transfer gas between the work and a surface of the electrode; and a control unit having electrostatic chucking electrodes so buried into the electrode surface as to form a plurality of independent regions, for controlling an in-plane distribution of a heat transfer gas pressure, controlling a DC voltage to be applied to each of the regions and further controlling a temperature distribution of the work.

The objects described above can be also accomplished by a plasma processing apparatus including a processing chamber having a vacuum exhaust device connected thereto and capable of reducing an internal pressure thereof, a device for supplying a gas into the processing chamber, a plasma generation unit for generating plasma inside the processing chamber and a unit for attracting and fixing a work or material to be processed onto an electrode whose temperature is controlled, by electrostatic force, including a plurality of independent grooves disposed on an electrode surface; a unit connected to the grooves, respectively, for supplying or exhausting a heat transfer gas; electrostatic chucking electrodes divided into a plurality of independent regions and buried into the electrode surface in such a fashion as to correspond to the grooves, respectively; and a unit for controlling an in-plane distribution of a heat transfer gas pressure between a work or material to be processed and the electrode surface, controlling a DC voltage to be applied to each of the regions and further controlling a temperature distribution of the work.

The objects described above can be further accomplished by a plasma processing method, wherein the temperature distribution of the work is controlled in each phase by arbitrarily changing the in-plane distribution of the heat transfer gas and the DC voltage to be applied to each of the regions when each phase of the plasma processing of the work is serially executed in a predetermined order. Furthermore, the objects can be accomplished by dividing an electrode surface into a plurality of independent ring-like regions and a round region at a center, and by providing a feed/exhaust unit for independently supplying or exhausting the heat transfer gas to or from each of the ring-like regions and the round region.

The objects described above can be further accomplished by dividing the electrode surface into a plurality of independent ring-like regions and a round region at a center, and providing a control unit for arranging an electrostatic chucking electrode to each of the ring-like regions and the round region and capable of independently controlling the DC voltage applied to each of the regions. Furthermore, the objects can be accomplished by elevating the heat transfer gas pressure at a portion at which a thermal conductivity between the electrode surface and the work is to be increased, further adjusting the DC voltage to be applied to the electrostatic chucking electrode to increase the chucking force or attraction force, lowering the heat transfer gas pressure at a portion at which the thermal conductivity between the electrode surface and the work is to be decreased, and further adjusting the DC voltage to be applied to the electrostatic chucking electrode to reduce the chucking force. The objects can be further accomplished by controlling the DC voltage to be applied to a region in which the chucking force between the work and the electrode surface is to be decreased to a potential equal, or substantially equal, to a self bias potential of the work during the plasma processing.

The objects described above can be accomplished by a method including the steps of reducing an internal pressure of a processing chamber by a vacuum exhaust device, supplying a gas into the processing chamber, generating plasma inside the processing chamber, attracting the work onto an electrode whose temperature is controlled, by electrostatic force, the method including the steps of supplying or exhausting a heat transfer gas from a plurality of independent regions on the electrode surface; controlling an in-plane distribution of the heat transfer gas pressure; controlling a DC voltage to be applied to each of regions of electrostatic chucking electrodes buried into the electrode surface in such a fashion as to correspond to said regions, respectively; and controlling a temperature distribution of the work.

The objects described above can be further accomplished by a method including the steps of reducing an internal pressure of a processing chamber by a vacuum exhaust device, supplying a gas into the processing chamber, generating plasma inside the processing chamber, and attracting the work onto an electrode whose temperature is controlled, by electrostatic force, the method including the steps of supplying or exhausting a heat transfer gas from a plurality of independent grooves on the electrode surface; controlling an in-plane distribution of the heat transfer gas pressure between the work and the electrode surface; controlling a DC voltage to be applied to each of regions of electrostatic chucking electrodes buried into the electrode surface in such a fashion as to correspond to the grooves, respectively; and controlling a temperature distribution of the work.

Furthermore, the objects described above can be accomplished by arbitrarily changing the in-plane distribution of the heat transfer gas and the DC voltage to be applied to each of regions when each phase of the plasma processing of the work is serially executed in a predetermined order to control the temperature distribution of the work.

According to the invention, it is possible to arbitrarily control the in-plane distribution of the thermal conductivity of the heat transfer gas in such a fashion as to achieve a desired wafer temperature distribution and to highly precisely regulate the in-plane distribution of the contact thermal conductivity between the wafer and the electrode surface. Therefore, it becomes possible to reduce influences of changes of a processing as seed, a processing pressure, a plasma distribution, radiation from sidewalls, etc, to bring the wafer temperature distribution close to a desired temperature distribution and to expand the control range of the wafer temperature.

In step etching that serially executes each step of an etching processing in accordance with a predetermined order to plasma process a laminate film on the wafer, the wafer temperature distribution can be changed at a high speed between the steps.

Furthermore, even when the surface roughness of the electrode surface changes with time owing to the plasma processing, the thermal conductivity at the contact zone can be minimized because the electrostatic chucking force is weak at that portion, and the influences of the surface roughness can be reduced. In other words, stability of wafer temperature control can be improved.

Other objects, features and advantages of the invention will become apparent from the following description of the embodiments of the invention taken in conjunction with the accompanying drawings.

### BRIEF DESCRIPTION OF THE DRAWINGS

FIG. 1 is a longitudinal sectional view showing an outline of a construction of a plasma processing apparatus according to an embodiment of the invention;

FIG. 2 is a longitudinal sectional view showing an outline of a construction of a wafer holding electrode as a sample table of the embodiment shown in FIG. 1;

FIG. 3 is a graph showing a temperature change of a wafer surface in a radial direction in the embodiment shown in FIG. 1;

FIG. 4 is a flowchart showing the flow of a wafer processing in the embodiment shown in FIG. 1;

FIG. 5 is a longitudinal sectional view showing an outline of a construction of a wafer holding electrode of a plasma processing apparatus according to the embodiment of the invention; and

FIG. 6 is a longitudinal sectional view showing an outline of a construction of a wafer holding electrode according to a modified embodiment of the embodiment shown in FIG. 5.

### DETAILED DESCRIPTION OF THE EMBODIMENTS

Embodiments of the invention will be hereinafter explained with reference to the accompanying drawings.

### Embodiment 1

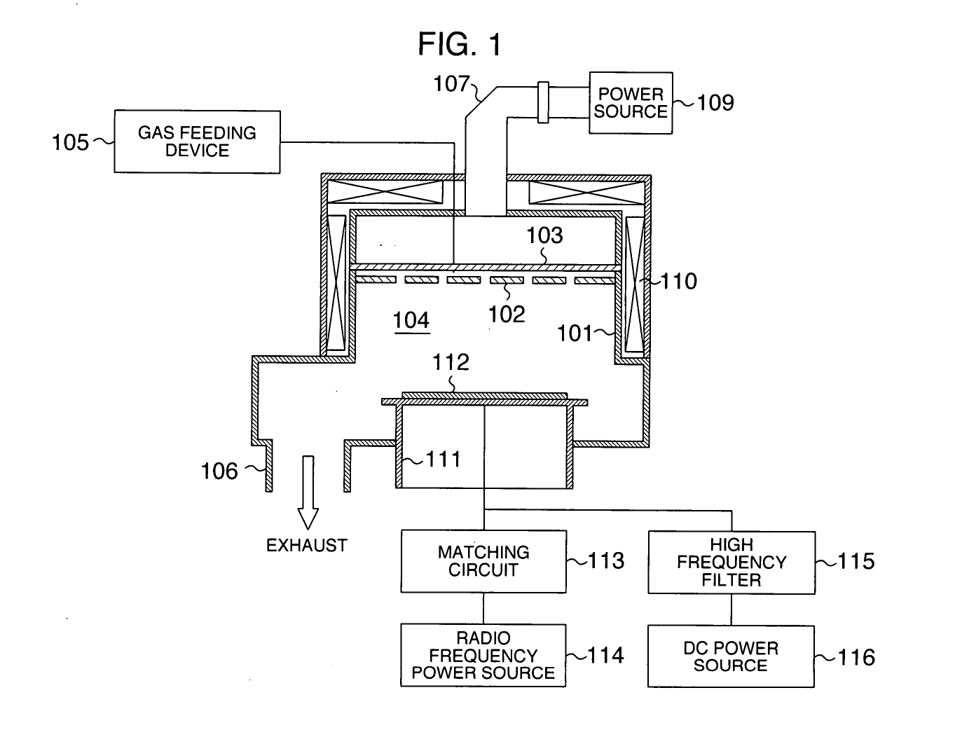

A microwave ECR (Electron Cyclotron Resonance) etching apparatus according to an embodiment of the invention will be hereinafter explained with reference to FIGS. 1 to 3. FIG. 1 is a longitudinal sectional view showing an outline of a construction of a plasma processing apparatus according to an embodiment of the invention

In the drawing, the plasma processing apparatus according to this embodiment includes a shower plate 102 (formed of quartz, for example) for introducing an etching gas into a vacuum vessel 101 and a dielectric window 103 (formed of quartz, for example) that are arranged at upper parts of the vacuum container 101 the upper part of which is open. A processing chamber 4 is formed when this vacuum vessel 101 is sealed. A gas feeding device 105 for causing the etching gas to flow is connected to the shower plate 102. A vacuum exhaust device (not shown in the drawing) is connected to the vacuum vessel 101 through a vacuum exhaust port 106.

A wave guide tube 107 (or antenna) is arranged above the dielectric window 103 to transfer power for generating plasma to the processing chamber 104. An electromagnetic wave transferred to the wave guide tube 107 (or antenna) is oscillated from a power source 109 for generating the electromagnetic wave. The frequency of the electromagnetic wave is not particularly limited and this embodiment uses a microwave of 2.45 GHz. A field generation coil 110 for generating a magnetic field is arranged round an outer peripheral portion of the processing chamber 104 and electric power oscillated by the electromagnetic wave generation power source 109 generates high density plasma inside the processing chamber 104 by interaction with the magnetic field generated.

A wafer holding electrode 111 is disposed at a lower part of the vacuum vessel 101 in such a manner as to oppose the shower plate 102. The electrode surface of the wafer holding electrode 111 is coated with a flame coating film (not shown) and a DC power source 116 is connected through a high frequency filter 115. A radio frequency power source 114 is further connected to the wafer holding electrode 111 through a matching circuit 113.

A wafer (or a work or a material to be processed) 112 conveyed into the processing chamber 104 is attracted onto the wafer holding electrode 111 by the electrostatic force of the DC voltage applied from the DC power source 116. After a desired etching gas is supplied from the gas feeding device 105, the internal pressure of the vacuum vessel 101 is set to a predetermined pressure and plasma is generated inside the processing chamber 104. As high frequency power is applied from the high frequency power source 114 connected to the wafer holding electrode 111, the ions are attracted from the plasma towards the wafer and the wafer 112 is etched.

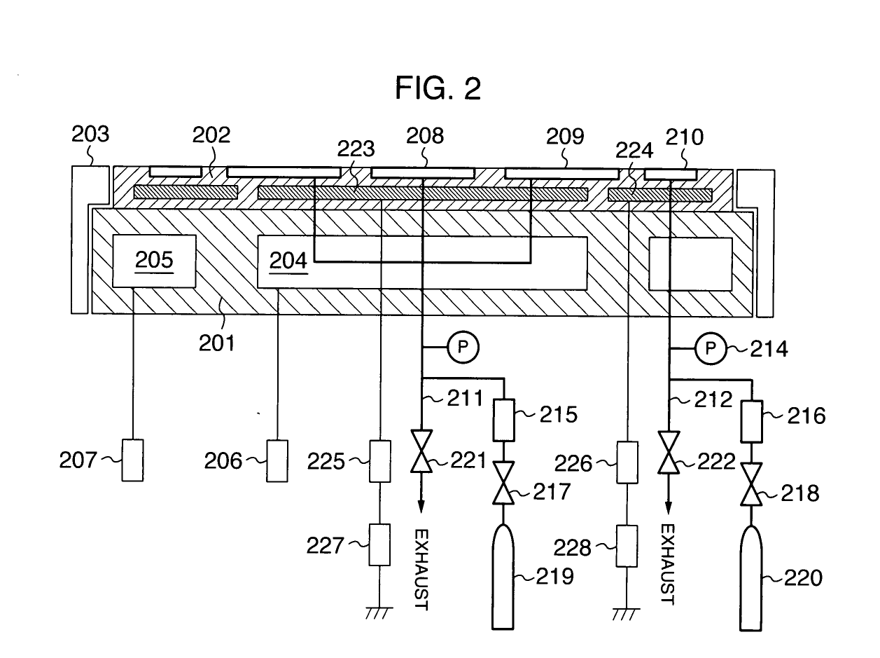

Next, the wafer holding electrode 111 in this embodiment will be explained with reference to FIG. 2. FIG. 2 is a longitudinal sectional view showing an outline of a construction of the wafer holding electrode as a sample table of the embodiment shown in FIG. 1. In the drawing, a flame coating film 202 formed of alumina, a susceptor 203 as an insulator, a first flow passage 204 through which a coolant for controlling the temperature of a round region on the center side of a structure 201, a second flow passage 205 through which a coolant for controlling the temperature of a ring-like region on the outer circumferential side of the structure 201 and first and second coolant temperature controllers 206 and 207 for independently controlling the temperatures of the coolants flowing in the flow passages to predetermined temperatures and circulating them, respectively, are connected to the substrate 201 as the structure of the wafer holding electrode 111 (hereinafter called “electrode”) used for the plasma processing apparatus of this embodiment.

When the plasma treatment is carried out, the wafer 112 is electrostatically attracted through the flame coating film 202 to the substrate 201 the temperature of which is controlled by the first and second coolant temperature controllers 206 and 207, and is temperature-controlled (cooled). Three heat transfer gas grooves 208, 209 and 210 for supplying the heat transfer gas are formed on the surface of the wafer holding electrode 111 between the wafer 112 and the flame coating film 202. The first heat transfer gas groove 208 is a round region at the center of the electrode surface. The second heat transfer gas groove 209 is a ring-like region disposed round the outer periphery of the first heat transfer gas groove 208. The third heat transfer gas groove 210 is a ring-like region formed round the outer periphery of the second heat transfer gas groove 209.

Piping arrangements 211, 212 and 213 for supplying the heat transfer gas, pressure gauges 213 and 214 for measuring the pressure between the wafer 112 and the flame coating film 202, gas flow rate controllers 215 and 216 for controlling the supply quantity of the heat transfer gas, valves 217 and 218 for supplying the heat transfer gas, gas bombs 219 and 220 and exhaust valves for the heat transfer gas 221 and 222 are connected to the first, second and third heat transfer gas grooves 208, 209, 210, respectively, that are arranged on the surface of the wafer holding electrode 111. In this embodiment, the first heat transfer gas groove 208 and the second heat transfer gas groove 209 are connected by one piping arrangement 211 and the heat transfer gas pressures are equal. A Unit for supplying or exhausting the heat transfer gas may be provided to each of the heat transfer gas groove.

Ring-like protuberances are arranged between the first to third heat transfer gas grooves 208 to 210 and at the outer peripheral edge of the water holding electrode 111 on the outer peripheral side of the third heat transfer gas groove 210. These protuberances come into contact with the back of the wafer 112 put on the surface of the protuberances and define and form space regions into which the heat transfer gas is supplied and charged, between the back of the wafer 112 and each of the first to third heat transfer gas grooves 208 to 210. These protuberances operate as seal members that seal the spaces among the first to third heat transfer gas grooves 208 to 210 and inside the processing chamber 104 when the wafer 112 is attracted and fixed to the surface of the wafer holding electrode 111 as will be described later and keep the heat transfer gas at a predetermined pressure.

When the plasma treatment is carried out, the heat transfer gas (helium gas in this embodiment) is supplied from the gas bombs 219 and 220 by opening the valves 217 and 218. The gas pressures inside the respective heat transfer gas grooves 208, 209 and 210 are monitored by the pressure gauges 213 and 214 and are controlled by the gas flow rate controllers 215 and 216 to attain a desired pressure. It is known that the thermal conductivity of heat transfer gases in general is proportional to the gas pressure. A higher heat transfer gas pressure is more effective for improving the heat transfer ratio. The improvement in the heat transfer performance is higher at a higher pressure from 1 kPa to 10 kPa but does not depend any more on the pressure above this level. In other words, heat conductivity between the electrode and the wafer in the heat transfer gas groove can be controlled by the pressure of the heat transfer gas charged. The heat transfer performance of the heat transfer gas cannot be expected from 0 kPa to 0.1 kPa. When it is desired to minimize heat conduction between the electrode and the wafer 112 in the heat transfer gas groove, heat insulation can be established by opening the gas exhaust valves 221 and 222 and bringing the heat transfer gas grooves 28, 209 and 210 into vacuum.

When the pressure of the heat transfer gas charged is uniform inside the wafer plane as in the plasma processing apparatus according to the prior art, the thermal conductivity is equal inside the wafer plane between the wafer and the electrode. When calorie flowing into the wafer is different inside the plane owing to changes resulting from the kind of the processing gas, the processing pressure, the plasma distribution and radiation from the side wall, the problem remains in that the temperature distribution inside the wafer plane cannot be rendered uniform. In contrast, when the pressures of the heat transfer gas between the wafer 112 and the electrode are discretely controlled by the independent heat transfer gas grooves 208, 209 and 210 on the electrode as in the plasma processing apparatus according to this embodiment, the thermal conductivity between the wafer 112 and the electrode can be brought into an arbitrary distribution inside the wafer plane. Consequently, even when the calorie flowing into the wafer is different inside the wafer plane, the temperature of the wafer can be rendered uniform. Because the thermal conductivity inside the wafer plane can be brought into an arbitrary distribution, the temperature distribution inside the wafer plane can be arbitrarily controlled to a convex distribution or a concave distribution, for example.

In the embodiment of the invention described above, the shape of the heat transfer grooves is an annular shape of a concentric circle or a round shape. When the shape is annular of a concentric circle or round, the in-plane distribution of the heat transfer gas pressure becomes symmetric with respect to a center axis and the temperature distribution inside the wafer plane can be more easily controlled.

Though the heat transfer gas grooves have three systems in this embodiment, the temperature distribution inside the wafer plane can be more accurately controlled by disposing four or more systems of heat transfer gas grooves.

It has not been possible in the past to control the contact thermal conductivity at the contact zone between the wafer and the electrode surface by merely controlling the pressure of the heat transfer gas because only the thermal conductivity at the grooves changes. In other words, the problem remains unsolved in that the controllable range of the temperature is narrow. In this embodiment, therefore, two independent electrostatic chucking electrodes 223 and 224 are arranged on the electrode surface. The first electrostatic chucking electrode 223 is disposed in the round region at the center of the electrode surface and the second electrostatic chucking electrode 224 is disposed in the annular region formed round the outer periphery of the first electrostatic chucking electrode 223. These electrodes are buried into the alumina flame coating film 202 on the surface of the substrate 201. Filters 225 and 226 for cutting off the transfer of radio frequency power and DC power sources 227 and 228 for applying a DC voltage to the electrostatic chucking electrodes are connected to the electrostatic chucking electrodes 223 and 224, respectively.

When the plasma processing is carried out, the DC voltages are applied from the DC power sources 227 and 228 and the wafer 112 is attracted to the electrode by electrostatic force generated. This chucking force can be controlled by the magnitude of the DC voltages applied and is decided by the difference between a self bias potential of the wafer and the DC voltages applied to the electrostatic chucking electrode 210 during the plasma processing. It is known that the contact thermal conductivity is generally proportional to the contact pressure (chucking force). The smaller the difference between the self bias potential and the DC voltage applied, the greater becomes the chucking force and the greater becomes the improvement of the heat transfer performance. The chucking force becomes minimal when the self bias potential and the DC voltage applied are equal to each other and the heat transfer performance cannot be expected. In other words, the contact thermal conductivity between the electrode surface and the wafer 112 at the contact zone with the wafer 112 can be controlled by the magnitude of the DC voltage and the contact thermal conductivity inside the wafer plane can be brought into an arbitrary distribution. Because the contact thermal conductivity at the contact zone with the wafer can be controlled, the variable range of the wafer temperature can be expanded.

In other words, the heat transfer gas pressure is elevated at the portion where the thermal conductivity between the wafer and the electrode surface is increased. The chucking force is increased by adjusting the DC voltage to be applied at the electrostatic chucking electrode of the region in which the heat transfer gas pressure is elevated. The heat transfer gas pressure is lowered at the portion where the thermal conductivity between the wafer and the electrode surface is to be lowered and the chucking force is decreased by adjusting the DC voltage to be applied at the electrostatic chucking electrode of the region in which the heat transfer gas pressure is lowered. In this way, the in-plane distribution of the wafer temperature can be controlled and the variable range of the wafer temperature can be further expanded.

Incidentally, the first, second and third heat transfer gas grooves 208, 209 and 210 are the regions to which the heat transfer gas is supplied in this embodiment. Concavo-convexities are formed inside these grooves and a part of them keeps contact with the back of the wafer 112 attracted and heat transfer is made at these contact zones. The contact areas of the surface keeping contact with the wafer 112 inside the first, second and third heat transfer gas grooves 208, 209 and 210 are smaller than the areas of the convex portions.

The electrostatic chucking electrode 223 on the center side of the substantial disk in this embodiment extends to the first heat transfer gas groove 208 and to the lower part of the ring-like convex portion outside the groove 208, and its outer peripheral edge extends to the lower part of the second heat transfer gas groove 209. The inner peripheral edge of the ring-like electrostatic chucking electrode 224 on the outer peripheral side is positioned below the second heat transfer gas groove 209 and its outer peripheral edge is positioned below the convex portion of the third heat transfer gas groove 210. In other words, the electrostatic chucking electrode 224 on the outer peripheral side extends to the second and third heat transfer gas grooves 209 and 210 and is positioned below these grooves 209 and 210. The contact force between the wafer 112 and the second and third heat transfer grooves 209 and 210 and between the wafer 112 and the convex portions between these grooves is adjusted when the DC voltage applied to the electrostatic chucking electrode 224 on the outer peripheral side is adjusted. The seal performance by the convex portions between the first and second heat transfer grooves 208 and 209 is adjusted, too.

In the embodiment of the invention described above, the shapes of the electrostatic chucking electrodes are annular of a concentric circle and round on the electrode surface. When the electrodes have such annular shape of a concentric circle and round shape, the in-plane distribution of the contact thermal conductivity due to the chucking force can be made symmetric with respect to a center axis and the temperature distribution inside the wafer plane can be more easily controlled. Though the electrostatic chucking electrodes have two regions in this embodiment, the temperature distribution inside the wafer plane can be controlled further precisely by using a plurality of regions, that is, two or more regions.

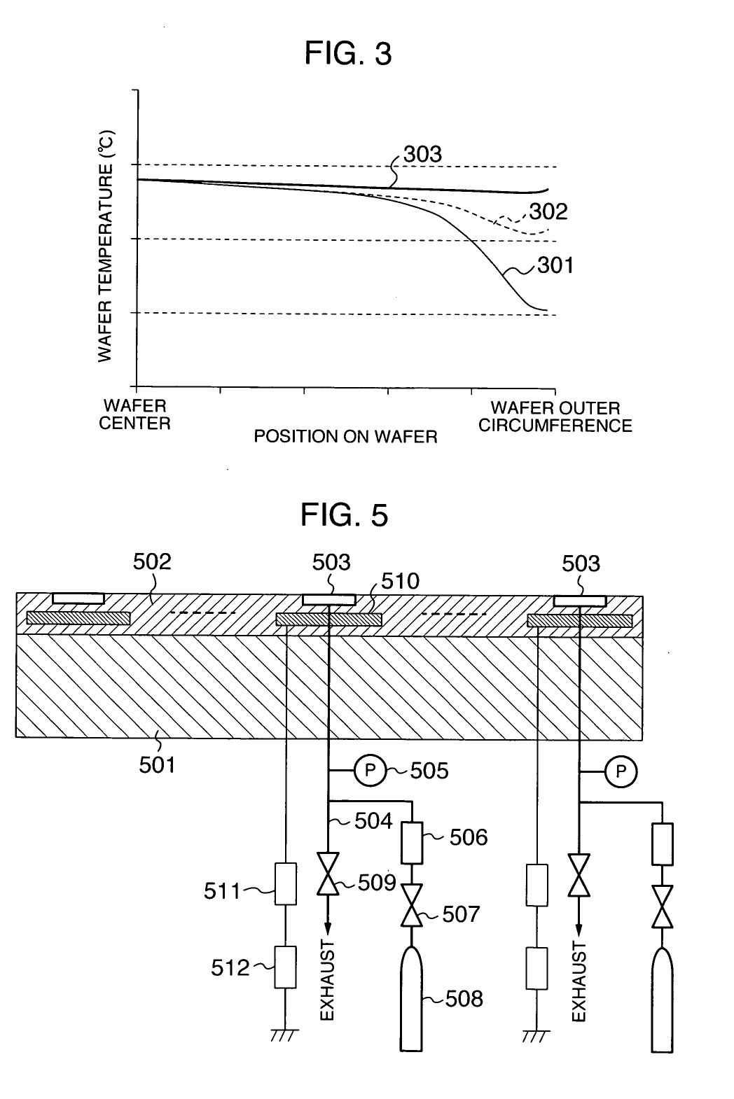

Next, FIG. 3 shows the actual result of the wafer temperature measurement. FIG. 3 is a graph showing the temperature change of the wafer surface of the embodiment shown in FIG. 1 in the radial direction. A curve 301 represents a wafer temperature distribution when the heat transfer gas pressures in the first, second and third heat transfer as grooves 208, 209 and 210 are all 1.0 kPa and the in-plane chucking force is kept constant by adjusting the DC voltage applied to the first and second electrostatic chucking electrodes 223 and 224. A curve 302 represents a wafer temperature distribution when the heat transfer gas pressures in the first and second heat transfer as grooves 208 and 209 are all 1.0 kPa, the heat transfer gas pressure in the third heat transfer gas groove 210 is 0 kPa and the in-plane chucking force is kept constant by adjusting the DC voltage applied to the first and second electrostatic chucking electrodes 223 and 224. A curve 303 represents a wafer temperature distribution when the heat transfer gas pressures in the first and second heat transfer as grooves 208 and 209 are all 1.0 kPa, the heat transfer gas pressure in the third heat transfer gas groove 210 is 0 kPa, the DC voltage to be applied to the first electrostatic chucking electrode 223 is the same as the voltages of the curves 301 and 302, the DC voltage to be applied to the second electrostatic chucking electrode 224 is equal to the self bias voltage during the plasma processing and the chucking force is rendered minimal.

When the thermal conductivity in the wafer plane is uniform, the wafer temperature distribution exhibits a convex distribution due to influences of the plasma distribution, etc, as indicated by the curve 301. In contrast, when the heat transfer gas pressure round the outer peripheral portion of the wafer and the thermal conductivity are lowered, the temperature round the wafer outer peripheral portion rises and uniformity of the temperature distribution can be improved as indicated by the curve 302. Furthermore, when the chucking force of the wafer outer peripheral portion is lowered, the thermal conductivity round the outer peripheral portion is further lowered and uniformity of the wafer temperature can be improved as indicated by the curve 303. It can be thus appreciated that the variable range of the wafer temperature becomes great by controlling the chucking force.

There is the case where the etching characteristics do not get uniform owing to the influences of the plasma distribution and the distribution of by-products in actual etching even when the wafer temperature distribution is made uniform inside the plane as indicated by the curve 303. On the contrary, there is the case where the etching characteristics become rather uniform inside the wafer plane when the temperature distribution inside the wafer plane is a convex distribution as represented by the curve 301. In such cases, too, this embodiment can achieve a desired wafer temperature distribution by arbitrarily controlling the thermal conductivity inside the wafer plane and can make uniform the etching characteristics inside the wafer plane.

As described above, time response of the wafer temperature control becomes extremely slow in the apparatus constituted as in this embodiment by using the unit for controlling the temperature distribution inside the wafer plane by the heat transfer gas pressure and the magnitude of the DC voltage applied to the electrostatic chucking electrodes. When a desired etching shape is acquired, it becomes possible to optimize the temperature distribution of the wafer in each step in step etching in which each step of the etching processing is serially executed in accordance with a predetermined sequence. Consequently, a high precision etching processing becomes possible and the working ratio of the apparatus as well as the yield of the devices can be improved.

In such an etching processing apparatus, there are many cases where a laminate film formed by depositing a plurality of materials onto a wafer is etched. The optimal plasma processing condition varies depending on the material of each film and the temperature distribution inside the wafer plane greatly changes during the plasma processing. Particularly, the distribution of CD (Critical Dimension) inside the wafer plane is greatly dependent on and strongly affected by the wafer temperature during the plasma processing. Therefore, in the plasma processing of the laminate film formed by depositing a plurality of materials, step etching becomes effective that serially executes each step under an optimal plasma processing condition for the material of each film. In the apparatus constituted as in this embodiment, the temperature distribution inside the wafer plane is controlled by the heat transfer gas pressure and the DC voltage applied to the electrostatic chucking electrodes. Therefore, the wafer temperature distribution can be controlled at a high speed in such a fashion as to correspond to each step in step etching. In other words, this embodiment has the effect of executing control so as to achieve a desired CD distribution.

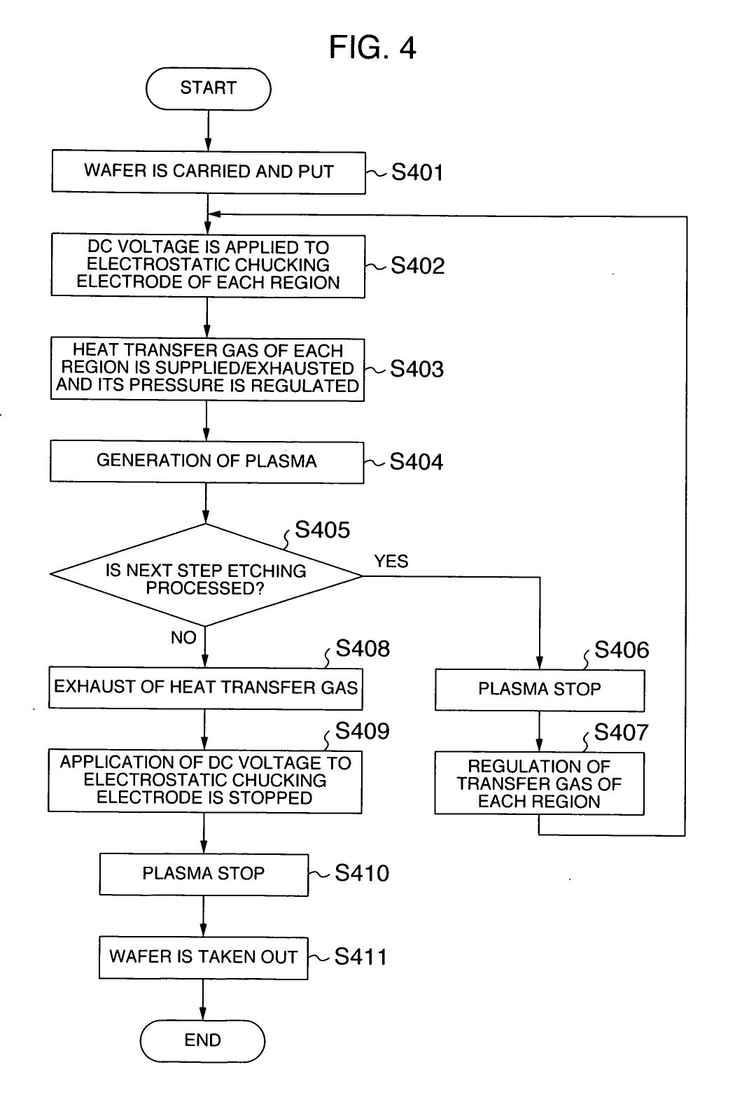

The flow of the processing operation when the laminate film described above is processed by the step etching processing. FIG. 4 is a flowchart showing the flow of the wafer processing in the embodiment shown in FIG. 1. First, the wafer 112 is put on the wafer holding electrode 111 (Step S401). Next, predetermined DC voltages are applied from the DC power sources 227 and 228, respectively, to electrostatically attract the wafer 112. At this time, the chucking force is increased by adjusting the DC voltage applied in the region of the electrostatic chucking electrode where the thermal conductivity between the wafer and the electrode surface is increased and the chucking force is decreased by adjusting the DC voltage applied in the region of the electrostatic chucking electrode where the thermal conductivity between the wafer and the electrode surface is decreased in such a fashion as to impart the wafer in-plane distribution of the contact thermal conductivity with the wafer (Step S402).

Next, the heat transfer gas from the gas bombs 219 and 220 is supplied or exhausted and control is made so that the gas pressures inside the heat transfer gas grooves 208, 209 and 210 attain desired pressures, respectively. At this time, the gas pressure for heat transfer is elevated in the region in which the thermal conductivity between the wafer and the electrode surface is increased and the gas pressure for heat transfer is lowered (exhausted) in the region in which the thermal conductivity between the wafer and the electrode surface is decreased to impart the wafer in-plane distribution of the thermal conductivity by the heat transfer gas between the wafer and the electrode surface (Step S403). Next, plasma is generated inside the processing chamber 104 and the wafer 112 is etched (Step S404). When the laminate film on the wafer is etched, the optimal plasma processing condition varies with the material of each film. In the case of step etching in which each step is serially executed under the optimal plasma processing condition for each film (Step S405), therefore, the temperature distribution inside the wafer plane greatly changes during the plasma processing in each step. Consequently, the wafer temperature distribution must be controlled at a high speed in such a manner as to correspond to each step. In other words, to conduct the etching processing of a next film, the voltage to be applied to each electrostatic chucking electrode and the heat transfer gas pressure in each region must be again adjusted to desired values.

When the step shifts to next step etching, plasma is first stopped (Step 406) and the heat transfer gas pressure in each region is regulated (Step 407). For example, when the chucking force is reduced to lower the contact thermal conductivity by the next step etching for the region in which the pressure of the heat transfer gas has been elevated, regulation such as exhausting of the heat transfer gas is made in advance for the region in which the chucking force is to be lowered because the wafer 112 peels from the wafer holding electrode 111 when the pressure of the heat transfer gas becomes higher than the chucking force (Step 407). Next, the DC voltage is again regulated to impart the wafer in-plane distribution of the contact thermal conductivity by regulating the DC voltage (Step S402) and the wafer in-plane distribution of the thermal conductivity by the gas by regulating the heat transfer gas pressure (Step S403). When all the step etching processing are completed (Step 405), the heat transfer gas is completely exhausted (Step 408), the application of the DC voltage to the electrostatic chucking electrodes is stopped (Step 409) and plasma is stopped (Step S410).

Lastly, the wafer 112 is removed from the wafer holding electrode 111 and is taken out from the processing chamber (Step S411). When the step etching processing is applied in the plasma processing method described above, plasma is stopped between the steps (Step S406) but plasma need not always be stopped between the steps. Namely, the voltage to be applied to the electrostatic chucking electrode and the in-plane distribution of the heat transfer gas pressure may well be controlled while the plasma processing is continued. In the plasma processing method demonstrated in this embodiment, the temperature distribution inside the wafer is controlled by controlling the DC voltage applied to the electrostatic chucking electrode and the heat transfer gas pressure. Consequently, the wafer temperature distribution can be controlled at a high speed in such a manner as to correspond to each step in step etching and the plasma processing can be executed in such a manner as to attain a desired CD distribution.

The contact thermal conductivity at the portion at which the wafer and the electrode keep mutual contact strongly depends on the surface roughness of the electrode surface when the heat transfer gas pressure is low. Therefore, when the surface roughness of the electrode surface changes with time owing to the plasma processing, stability of the wafer temperature is affected and the yield gets deteriorated. According to this embodiment, however, the chucking force can be lowered by controlling the DC voltage to the electrostatic chucking electrode. The influences of the surface roughness can be minimized by further lowering the chucking force at the portion at which the heat transfer gas pressure is lowered. Consequently, etching performance can be improved in the etching processing.

The foregoing embodiment has been explained about the etching apparatus utilizing the microwave ECR discharge by way of example but the same function and operation can be acquired in dry etching apparatuses utilizing other discharges (magnetic field UHF discharge, capacitance coupling type discharge, induction coupling type discharge, magnetron discharge surface wave excitation discharge, transfer coupled discharge). Though the foregoing embodiment has been explained about the etching apparatus, the same function and operation can be acquired for other plasma processing apparatuses for executing the plasma processing such as a plasma CVD apparatus, an ashing apparatus, a surface modifying apparatus, and so forth.

### Embodiment 2

The second embodiment of the invention will be explained with reference to FIG. 5. FIG. 5 is a longitudinal sectional view showing an outline of a construction of a wafer holding electrode of a plasma processing apparatus according to this embodiment. The difference of this drawing from Embodiment 1 will be explained. FIG. 5 shows a wafer holding electrode according to this embodiment of the invention. The wafer holding electrode 111 (hereinafter called “electrode”) used for the plasma processing apparatus of this embodiment includes a substrate 501 as an electrode structure, a flame coating film 502 of alumina and a temperature controller (not shown) for the substrate 501.

A plurality of independent heat transfer grooves 503 for supplying a heat transfer gas is formed on the electrode surface between a wafer 112 and the flame coating film 502. A piping arrangement 504 for supplying the heat transfer gas, a pressure gauge 505 for measuring the pressure between the wafer 112 and the flame coating film 502, a gas flow rate controller 506 for controlling the feed amount of the heat transfer gas, a gas bomb 508 and an exhaust valve 509 for the heat transfer gas are connected mutually independently to each of these independent heat transfer gas grooves 503.

When a plasma processing is carried out, the valve 507 is opened to supply the heat transfer gas (helium gas in this embodiment) from the gas bomb 508, the gas pressure inside the respective heat transfer gas groove 503 is monitored by the pressure gauge 505 and the gas flow rate controller 506 is controlled in such a manner as to achieve a desired pressure.

When the heat transfer gas pressures between the wafer 112 and the electrode are individually controlled by these independent heat transfer gas grooves 503, the thermal conductivity between the wafer 112 and the electrode can be brought into an arbitrary distribution inside a wafer plane. Because a plurality of independent heat transfer gas grooves 503 is disposed, the thermal conductivity inside the wafer plane can be more precisely controlled into an arbitrary distribution.

In this embodiment, a plurality of independent electrostatic chucking electrodes 510 is further disposed in such a manner as to correspond to a plurality of heat transfer gas grooves 503 formed on the electrode surface, respectively. Each of the electrostatic chucking electrodes 510 has a filter 511 for cutting off the transfer of radio frequency power and a DC power source 512 for applying a DC voltage to the electrostatic chucking electrodes that are connected to the electrode 510. The wafer 112 can be attracted onto the electrode by the force of static electricity that is generated when the DC voltage is applied from the DC power source 512. This chucking force can be controlled by the magnitude of the DC voltage applied.

As described above, the contact thermal conductivity between the electrode surface and the wafer 112 at the contact zone other than the grooves can be controlled by the magnitude of the DC voltage and the contact thermal conductivity inside the wafer plane can be brought into an arbitrary distribution. Furthermore, because the contact thermal conductivity at the contact zone of the wafer corresponding to the groove is controllable in addition to the control of the heat transfer gas pressure at the groove, the control range of the wafer temperature can be expanded and the temperature distribution inside the wafer plane can be controlled highly precisely.

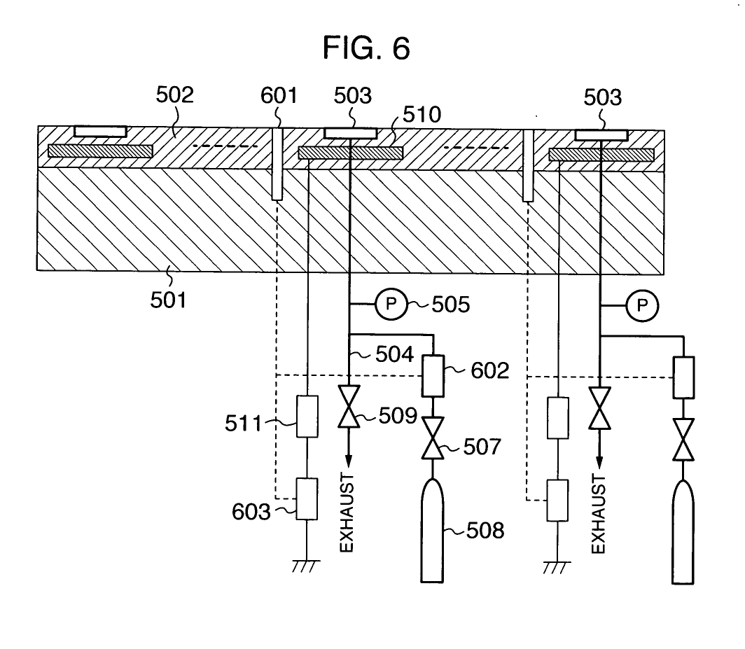

A modified embodiment of the embodiment described above will be explained with reference to FIG. 6. FIG. 6 is a longitudinal sectional view showing an outline of a construction of a wafer holding electrode of the modified embodiment shown in FIG. 5. The difference of this drawing from FIGS. 1 and 2 will be explained.

A temperature sensor 601 for detecting a temperature distribution of the wafer 112 during the plasma processing is provided to the electrode. The gas flow rate of the gas flow rate controller 602 and the output voltage of the DC power source 603 are controlled so that the temperature of the wafer during the plasma processing acquired from the temperature sensor 601 achieves a temperature distribution that is in advance determined. In other words, the in-plane distribution of the wafer temperature during the plasma processing is measured so that the in-plane distribution of the heat transfer gas pressure or the DC voltage applied to each region can be automatically controlled. In this way, the temperature distribution inside the wafer plane can be highly precisely controlled.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus including a processing chamber having a vacuum exhaust device connected thereto and capable of reducing an internal pressure thereof, a device for supplying a gas into said processing chamber, plasma generation means for generating plasma inside said processing chamber and means for attracting and fixing a work onto an electrode the temperature of which is controlled, by electrostatic force, comprising:
a plurality of feed/exhaust means for independently supplying or exhausting a heat transfer gas between said work and a surface of said electrode; and
control means having electrostatic chucking electrodes so buried into said electrode surface as to form a plurality of independent regions, for controlling an in-plane distribution of a heat transfer gas pressure, controlling a DC voltage to be applied to each of said regions and further controlling a temperature distribution of said work.

2. A plasma processing apparatus as defined in claim 1, wherein said control means arbitrarily changes the in-plane distribution of said heat transfer gas pressure and a DC voltage applied to each of said regions in each phase when each phase of a plasma processing is serially executed for said work in accordance with a predetermined order to control the temperature distribution of said work in each phase.

3. A plasma processing apparatus as defined in claim 1, wherein said electrode surface is divided into a plurality of independent ring-like regions and a round region at a center, and said feed/exhaust means independently supplies or exhausts the heat transfer gas to or from each of said ring-like regions and said round region.

4. A plasma processing apparatus as defined in claim 1, wherein said electrode surface is divided into a plurality of independent ring-like regions and a round region at a center, and said control means includes means that arranges an electrostatic chucking electrode in each of said ring-like regions and said round region and can independently control the DC voltage applied to each of said regions.

5. A plasma processing apparatus as defined in claim 1, wherein said control means elevates the heat transfer gas pressure at a portion at which a thermal conductivity between the electrode surface and said work is to be increased, further adjusts the DC voltage to be applied to said electrostatic chucking electrode to increase the chucking force, lowers the heat transfer gas pressure at a portion at which the thermal conductivity between the electrode surface and said work is to be decreased, and further adjusts the DC voltage to be applied to said electrostatic chucking electrode to reduce the chucking force.

6. A plasma processing apparatus as defined in claim 1, wherein said control means controls the DC voltage to be applied to a region in which the chucking force between said work and the electrode surface is to be decreased to a potential equal, or substantially equal, to a self bias potential of said work during the plasma processing.

7. A plasma processing apparatus including a processing chamber having a vacuum exhaust device connected thereto and capable of reducing an internal pressure thereof, a device for supplying a gas into said processing chamber, plasma generation means for generating plasma inside said processing chamber and means for attracting and fixing a work onto an electrode the temperature of which is controlled, by electrostatic force, comprising:
a plurality of independent grooves disposed on an electrode surface;
means connected to said grooves, respectively, for supplying or exhausting a heat transfer gas;
electrostatic chucking electrodes divided into a plurality of independent regions and buried into the electrode surface in such a fashion as to correspond to said grooves, respectively; and
means for controlling an in-plane distribution of a heat transfer gas pressure between a work and the electrode surface, controlling a DC voltage to be applied to each of said regions and further controlling a temperature distribution of said work.

8. A plasma processing apparatus as defined in claim 7, wherein said control means arbitrarily changes the in-plane distribution of said heat transfer gas pressure and a DC voltage applied to each of said regions in each phase when each phase of a plasma processing is serially executed for said work in accordance with a predetermined order to control the temperature distribution of said work in each phase.

9. A plasma processing apparatus as defined in claim 7, wherein said electrode surface is divided into a plurality of independent ring-like regions and a round region at a center, and said feed/exhaust means independently supplies or exhausts the heat transfer gas to or from each of said ring-like regions and said round region.

10. A plasma processing apparatus as defined in claim 7, wherein said electrode surface is divided into a plurality of independent ring-like regions and a round region at a center, and said control means includes means that arranges an electrostatic chucking electrode in each of said ring-like regions and said round region and can independently control the DC voltage applied to each of said regions.

11. A plasma processing apparatus as defined in claim 7, wherein said control means elevates the heat transfer gas pressure at a portion at which a thermal conductivity between the electrode surface and said work is to be increased, further adjusts the DC voltage to be applied to said electrostatic chucking electrode to increase the chucking force, lowers the heat transfer gas pressure at a portion at which the thermal conductivity between the electrode surface and said work is to be decreased, and further adjusts the DC voltage to be applied to said electrostatic chucking electrode to reduce the chucking force.

12. A plasma processing apparatus as defined in claim 7, wherein said control means controls the DC voltage to be applied to a region in which the chucking force between said work and the electrode surface is to be decreased to a potential equal, or substantially equal, to a self bias potential of said work during the plasma processing.

13. A method for plasma processing a work by reducing an internal pressure of a processing chamber by a vacuum exhaust device, supplying a gas into said processing chamber, generating plasma inside said processing chamber, attracting said work onto an electrode the temperature of which is controlled, by electrostatic force, comprising the steps of:
supplying or exhausting a heat transfer gas between said work and said electrode surface from a plurality of regions on said electrode surface;
controlling an in-plane distribution of the heat transfer gas pressure;
controlling a DC voltage to be applied to each of regions of electrostatic chucking electrodes buried into said electrode surface in such a fashion as to form a plurality of independent regions; and
controlling a temperature distribution of said work.

14. A plasma processing method as defined in claim 13, wherein the temperature distribution of said work is controlled in each phase by arbitrarily changing the in-plane distribution of the heat transfer gas and the DC voltage to be applied to each of said regions when each phase of the plasma processing of said work is serially executed in a predetermined order.

15. A method for plasma processing a work by reducing an internal pressure of a processing chamber by a vacuum exhaust device, supplying a gas into said processing chamber, generating plasma inside said processing chamber, attracting said work onto an electrode whose temperature is controlled, by electrostatic force, comprising the steps of:
supplying or exhausting a heat transfer gas from a plurality of independent grooves formed on said electrode surface;
controlling an in-plane distribution of the heat transfer gas pressure between said work and said electrode surface;
controlling a DC voltage to be applied to each of regions of electrostatic chucking electrodes buried into said electrode surface in such a fashion as to correspond to said grooves, respectively; and
controlling a temperature distribution of said work.

16. A plasma processing method as defined in claim 15, wherein the temperature distribution of said work is controlled in each phase by arbitrarily changing the in-plane distribution of the heat transfer gas and the DC voltage to be applied to each of said regions when each phase of the plasma processing of said work is serially executed in a predetermined order.
